(19) United States
(12) Patent Application Publication
(10) Pub. No.: US 2025/0380425 A1
(43) Pub. Date: Dec. 11, 2025

(54) BIPOLAR TRANSISTOR WITH FERROELECTRIC MATERIAL

(71) Applicant: GLOBALFOUNDRIES Dresden Module One Limited Liability Company & Co. KG, Dresden (DE)

(72) Inventors: Ulrich Wiesenhütter, Dresden (DE); Stefan Dünkel, Dresden (DE)

(21) Appl. No.: 18/734,527

(22) Filed: Jun. 5, 2024

(51) Int. Cl. H10B 51/30

(52) U.S. Cl. CPC H10B 51/30

(57) ABSTRACT

The present disclosure relates to semiconductor structures and, more particularly, to a bipolar transistor with ferroelectric material and methods of manufacture. The structure comprises: a lateral bipolar transistor; and a ferroelectric switching element electrically coupled to the lateral bipolar transistor.

### BACKGROUND

The present disclosure relates to semiconductor structures and, more particularly, to a bipolar transistor with ferroelectric material and methods of manufacture.

Bipolar transistors can be vertical transistors or lateral transistors. In a vertical bipolar transistor, carriers flow in a vertical direction; whereas in a lateral transistor, carrier flow in a lateral direction. In either configuration, the underlying semiconductor substrate can be implanted with a concentration of dopant, e.g., N+ dopant for a PNP device, to permanently program the electrical characteristics of the device.

### SUMMARY

In an aspect of the disclosure, a structure comprises: a lateral bipolar transistor; and a ferroelectric switching element electrically coupled to the lateral bipolar transistor.

In an aspect of the disclosure, a lateral bipolar transistor comprises: a first diffusion region; a second diffusion region adjacent to the first diffusion region; and a third diffusion region adjacent to the second diffusion region; an independently controlled ferroelectric material between the second diffusion region and the third diffusion region; and a contact electrically coupled to the ferroelectric material.

In an aspect of the disclosure, a method comprises: forming a lateral bipolar transistor; and forming a ferroelectric switching element electrically coupled to the lateral bipolar transistor.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a device and respective fabrication processes in accordance with aspects of the present disclosure.

FIG. 2 shows a top view of the device in accordance with aspects of the present disclosure.

FIGS. 3A and 3B representatively show a voltage applied to a ferroelectric material in accordance with aspects of the present disclosure.

FIGS. 4A-4G show a process flow for manufacturing the device in accordance with aspects of the present disclosure.

### DETAILED DESCRIPTION

The present disclosure relates to semiconductor structures and, more particularly, to a bipolar transistor with ferroelectric material and methods of manufacture. More specifically, in embodiments, the bipolar transistor may be a lateral bipolar transistor with ferroelectric material which acts as a base switch. In embodiments, a contact may be provided to the ferroelectric material to supply a voltage to the ferroelectric material. In this way, the lateral bipolar transistor can be tunable (e.g., switched) by providing a positive voltage or a negative voltage to the ferroelectric material. The thickness of the ferroelectric material can also be adjusted to provide a further set the electrical characteristics of the device. Advantageously, by using the ferroelectric material, it is now possible to tune critical parameters of the bipolar transistors during normal operation, i.e., programmable VBE, Beta and breakdown voltage. Moreover, the bipolar transistor may have the same footprint as a conventional bipolar transistor, and can also be manufactured with existing manufacturing processes.

The bipolar transistor of the present disclosure can be manufactured in a number of ways using a number of different tools. In general, though, the methodologies and tools are used to form structures with dimensions in the micrometer and nanometer scale. The methodologies, i.e., technologies, employed to manufacture the bipolar transistor of the present disclosure have been adopted from integrated circuit (IC) technology. For example, the structures are built on wafers and are realized in films of material patterned by photolithographic processes on the top of a wafer. In particular, the fabrication of the bipolar transistor uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

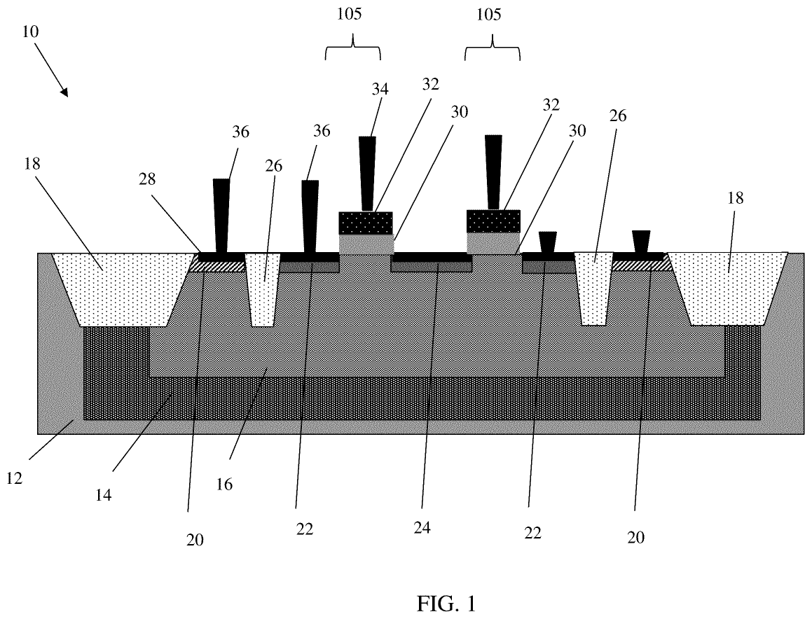

FIG. 1 shows a device and respective fabrication processes in accordance with aspects of the present disclosure. In embodiments, the device 10 may be a PNP or NPN lateral bipolar transistor. In either scenario, the device 10 includes a base switch 105 comprising ferroelectric material 30. The base switch 105 can be used to provide a positive voltage or negative voltage to the base region, thereby tuning the base to emitter voltage (VBE), beta and breakdown voltage of the collector to emitter (BVCEO).

In embodiments, the device 10 includes a deep well 14 and a shallow well 16 in a semiconductor substrate 12. The semiconductor substrate 12 may be bulk semiconductor material, e.g., Si, or, alternatively, a semiconductor-on-insulator (SOI) substrate, which can be fabricated using wafer bonding, and/or other suitable methods. The semiconductor substrate 12 may be composed of any suitable material including, but not limited to, Si, SiGe, SiGeC, SiC, GaAs, InAs, InP, and other III/V or II/VI compound semiconductors. The semiconductor substrate 12 may comprise any suitable single crystallographic orientation (e.g., a (100), (110), (111), or (001) crystallographic orientation).

Still referring to FIG. 1, for a PNP device, the deep well 14 and the shallow well 16 may be N-wells; whereas for an NPN device, the deep well 14 and the shallow well 16 may be P-wells. In embodiments, the shallow well 16 may be within the deep well 14. The wells 14, 16 may be formed by conventional ion implantation processes.

In more specific embodiments, the wells 14, 16 may be formed by introducing a dopant by, for example, ion implantation that introduces a concentration of a dopant in the semiconductor substrate 12. In embodiments, patterned implantation masks may be used to define selected areas exposed for the implantations. The implantation masks may include a layer of a light-sensitive material, such as an organic photoresist, applied by a spin coating process, pre-baked, exposed to light projected through a photomask, baked after exposure, and developed with a chemical developer. The implantation masks have a thickness and stopping power sufficient to block masked areas against receiving a dose of the implanted ions. For a PNP device, the wells 14, 16 are doped with n-type dopants, e.g., Arsenic (As), Phosphorus (P) and Antimony (Sb), among other suitable examples. For an NPN device, the wells 14, 16 are doped with p-type dopants, e.g., Boron (B). An annealing process may be performed to drive in the dopant into the semiconductor substrate 12.

Still referring to FIG. 1, diffusion regions 20, 22, 24 may be provided within the well 16. In embodiments, the diffusion region 20 may be a base region, the diffusion region 22 may be a collector region and the diffusion region 24 may be an emitter region. For a PNP, the diffusion region 20 may be a P+ diffusion region and the diffusion region 22 may be an N+ diffusion region; whereas for an NPN, the diffusion region 20 may be an N+ diffusion region and the diffusion region 22 may be a P+ diffusion region. The diffusion regions 20, 22, 24 may be formed by an ion implantation process with respective masks as already described herein.

The base region (e.g., diffusion region 20) and the collector region (e.g., diffusion region 22) may be electrically isolated from each other by a shallow trench isolation structure 26. In addition, the wells 14, 16 may be bound by a shallow trench isolation structure 18. The isolation structures 18, 26 may be formed by conventional lithography, etching and deposition methods known to those of skill in the art.

By way of example, a resist formed over the semiconductor substrate 12 is exposed to energy (light) and developed utilizing a conventional resist developer to form a pattern (opening). An etching process with a selective chemistry, e.g., reactive ion etching (RIE), will be used to transfer the pattern from the photoresist layer to the semiconductor substrate 12 to form one or more trenches in the semiconductor substrate 12 through the openings of the resist. Following the resist removal by a conventional oxygen ashing process or other known stripants, the insulator material, e.g., silicon dioxide, can be deposited by any conventional deposition processes, e.g., chemical vapor deposition (CVD) processes. Any residual material on the surface of the semiconductor substrate 12 can be removed by conventional chemical mechanical polishing (CMP) processes.

A silicide contact 28 may be formed on the diffusion regions 20, 22, 24. As should be understood by those of skill in the art, the silicide process begins with deposition of a thin transition metal layer, e.g., nickel, cobalt or titanium, over the diffusion regions 20, 22, 24. After deposition of the material, the structure is heated allowing the transition metal to react with exposed silicon (or other semiconductor material as described herein) in the active regions of the semiconductor device (e.g., diffusion regions 20, 22, 24) forming a low-resistance transition metal silicide. Following the reaction, any remaining transition metal is removed by chemical etching, leaving silicide contacts 28 in the active regions of the device 10. A silicide block material, e.g., nitride, may be used to prevent silicide contacts from forming on other exposed portions of the semiconductor substrate 12.

FIG. 1 further shows the base switch 105 comprising ferroelectric material 30 over the well 16 and between the diffusion regions 22, 24, e.g., between the collector region and the emitter region. As should be understood by those of skill in the art, the ferroelectric material 30 can maintain and reverse its electric polarization, e.g., change the direction of polarization by altering the direction of voltage. For example, ferroelectric material 30 exhibits a polarization that can be reversed by applying an opposite field with an external voltage.

In embodiments, the ferroelectric material 30 may be a single layer of ferroelectric material or multiple layers of ferroelectric material. In the latter example, the ferroelectric material 30 may be multiple mono-layers of ferroelectric material 30. The ferroelectric material 30 may be HZO (HF₁₋ₓZrₓO₂), Hafnium Oxide, Barium Titanate, Lead Zirconate Titanate or other known ferroelectric materials. In an illustrative, non-limiting example, ferroelectric polarization switching of a 10 nm thick HfSiO-film may be equivalent to an implant dose change of 6E13 cm⁻². It should be understood that a thicker layer of ferroelectric material 30 will have a larger impact on device performance, e.g., equivalent to a higher implant dosage.

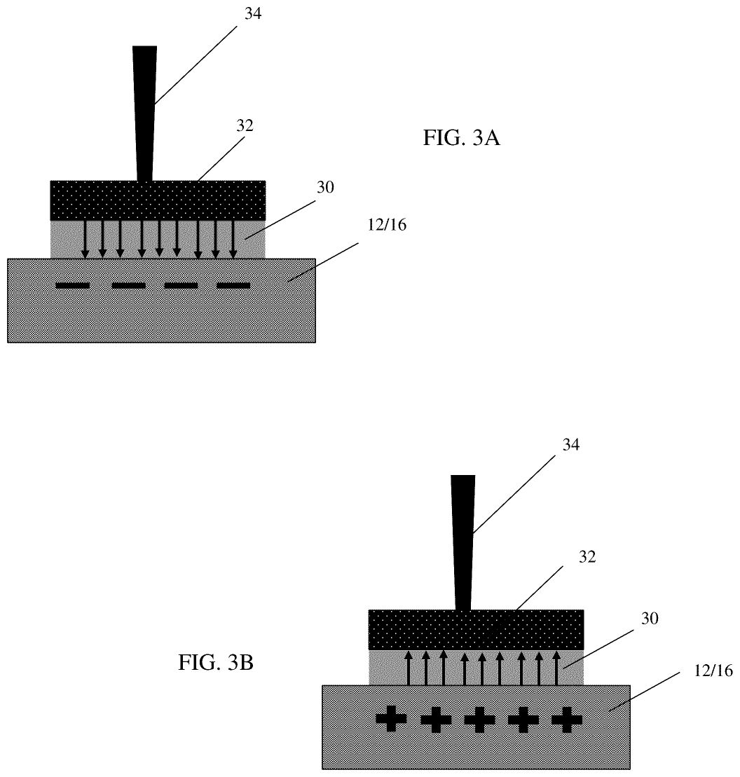

A metal material 32 may be provided on the ferroelectric material 30. In embodiments, the metal material 32 may be any back-end-of-the-line (BEOL) metal material. For example, the ferroelectric material 30 may be TiN, Al, W or Cu, etc. Contacts 34 are provided to the metal material 32 and contacts 36 are provided to the diffusion regions 20, 22, 24. The contacts 34 may be used to independently supply a voltage to the ferroelectric material 30 which results in the polarization of the ferroelectric material 30, e.g., switching the underlying semiconductor substrate 12 to positive or negative. Accordingly, and as described in more detail with respect to FIGS. 3A and 3B, the contacts 34 may be used to independently switch the polarization in order to tune the base region.

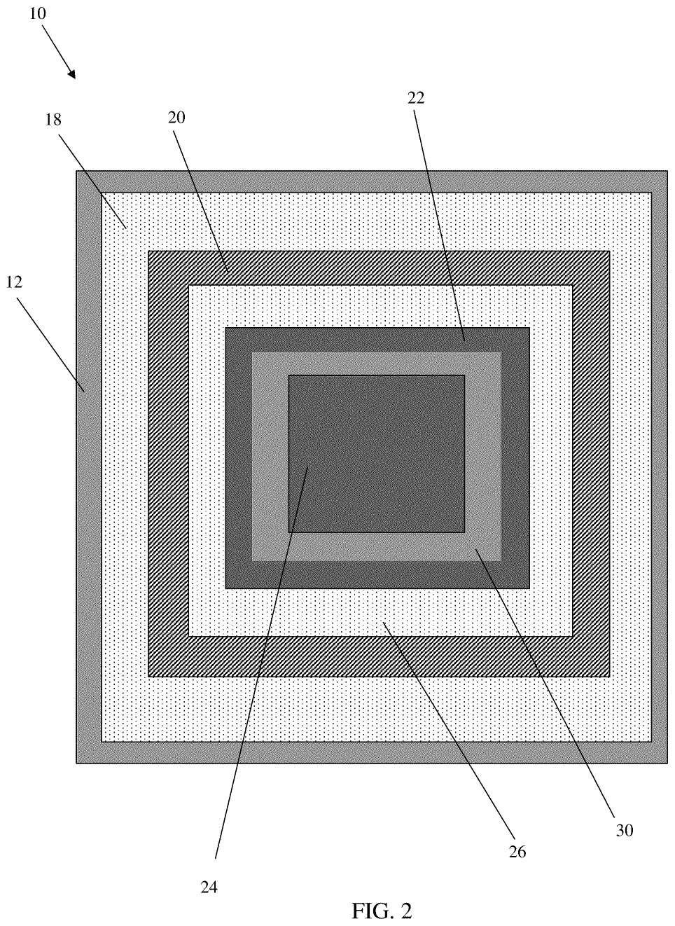

FIG. 2 shows a top view of the device 10 in accordance with aspects of the present disclosure. As shown in this view, the shallow trench isolation structure 18 surrounds the diffusion region 20, e.g., base region. The shallow trench isolation structure 18 isolates the diffusion region 20 from the semiconductor substate 12. Similarly, the diffusion region 20 surrounds the shallow trench isolation structure 26. The shallow trench isolation structure 26 isolates the diffusion region 20 from the diffusion region 22 (e.g., collector region). The ferroelectric material 30 is provided between the diffusion region 20 and the diffusion region 24 (e.g., emitter region). No additional area is needed for the ferroelectric material 30 and contact 34, e.g., base-switch, which can be independently polarized by application of a voltage.

FIGS. 3A and 3B representatively show different voltages being applied to the ferroelectric material 30. For example, FIG. 3A shows a positive voltage pulse being applied to the ferroelectric material 30 and FIG. 3B shows a negative voltage pulse being applied to the ferroelectric material 30. The applied voltage may be, for example, +/−3V; although other voltages are also contemplated herein depending on the desired characteristics of the device 10.

In FIG. 3A, the positive voltage will attract negative charges (electrons) equivalent to higher doping of the semiconductor substrate 12; whereas in FIG. 3B, the negative voltage attracts positive charges (holes) equivalent to lower doping of the semiconductor substrate 12. In the example of FIG. 3A, the application of a positive voltage will lower the base to emitter voltage (VBE) and will increase the beta and breakdown voltage of the collector to emitter (BVCEO). In contrast, in the example of FIG. 3B, the application of a negative voltage will raise the base to emitter voltage (VBE) and will decrease the beta and breakdown voltage of the collector to emitter (BVCEO). Accordingly, as shown representatively in FIGS. 3A and 3B, the polarization of the ferroelectric material 30 may be switched to achieve a desired shift in an I-V curve (Current vs. Voltage curve).

In operation, the switching of the polarization of the ferroelectric material 30 may be performed prior to normal use of the transistor, e.g., lateral PNP or NPN. Also, it should be understood that the transistor may be provided in a normal operation mode by not applying a voltage to the ferroelectric material 30, e.g., the base-switch is turned off. Also, the polarization of the ferroelectric material 30 may be tuned continuously from up to down, e.g., positive to negative voltage applications. Moreover, it should be understood that the polarization state may be stable even without further electrical voltage supply (non-volatile) and can be re-programmed at any time with existing I/O-voltages.

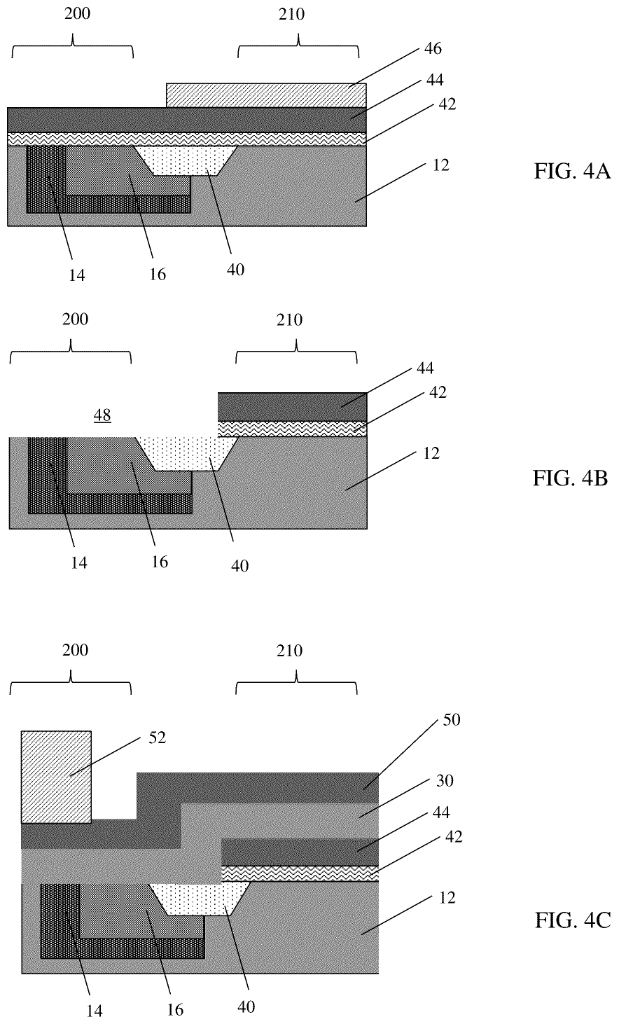

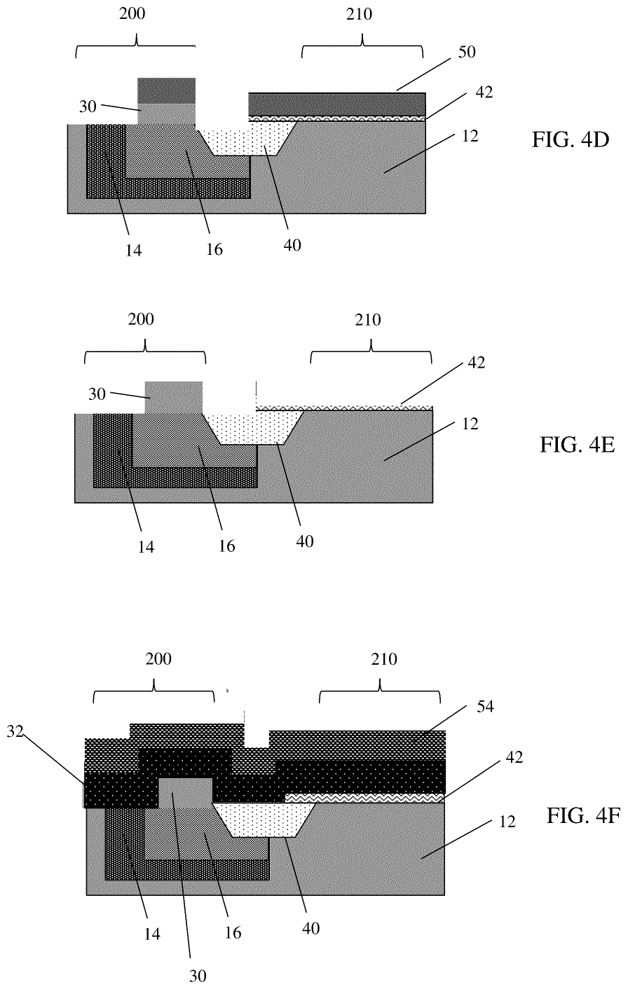

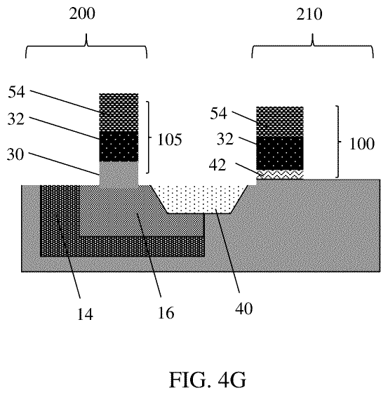

FIGS. 4A-4G show processes for manufacturing the device in accordance with aspects of the present disclosure. The processes shown in FIGS. 4A-4G may be representative of a lateral PNP or lateral NPN, depending on the doping type used for the wells and diffusion regions. The processes of FIGS. 4A-4G also show the formation of a gate structure for a logic device as depicted by reference number 100 in FIG. 4G. In the process flow of FIGS. 4A-4G, the region designated 200 is representative of a side of the structure with the lateral bipolar transistor and base switching element, e.g., ferroelectric material, and the region designated 210 is representative of a side of the structure with the logic device 100.

In FIG. 4A, the wells 14, 16 are formed in the semiconductor substrate 12 in region 200. As described above, the wells 14, 16 may be formed by a conventional ion implantation process used in a lateral bipolar transistor. FIG. 4A also shows a shallow trench isolation structure 40 providing an isolation region between regions 200, 210. In more specific embodiments, the shallow trench isolation structure 40 may be used to isolate the lateral bipolar device in region 200 from a conventional logic device 100 in FIG. 4G in region 210. The shallow isolation structure 40 may be formed by conventional lithography, etching and deposition methods as already described herein.

FIG. 4A further shows the formation of a gate dielectric material 42 over the semiconductor substrate 12. In embodiments, the gate dielectric material 42 may be a high-k dielectric material such as, for example, a hafnium based oxide. The gate dielectric material 42 may be deposited using conventional deposition methods including, for example, atomic layer deposition (ALD), plasma enhanced chemical vapor deposition (PECVD), etc.

FIG. 4A also shows a hardmask material 44 formed over the gate dielectric material 42. In embodiments, the hardmask material 44 may be silicon nitride or other known hardmask material. The hardmask material 44 may be deposited using a conventional deposition method, e.g., CVD. A photolithographic resist 46 may be deposited on the hardmask material 44 and patterned using conventional lithography processes. In this representation, the photolithographic resist 46 will protect the hardmask material 44 and gate dielectric material 42 in region 210, e.g., the side of the subsequently formed device 100 shown in FIG. 4G.

In FIG. 4B, the exposed hardmask material 44 and gate dielectric material 42 are removed by conventional etching processes, e.g., RIE. This will form an opening 48 partially over and on a side of the shallow trench isolation structure 40. Accordingly, the semiconductor substrate 12 will be exposed in region 200, e.g., on the side of the subsequently formed bipolar transistor with the ferroelectric material. The photolithographic resist 46 may be removed by using conventional stripants or an ashing process as already described herein.

As further shown in FIG. 4C, a ferroelectric material 30 may be formed on the exposed hardmask material 44, shallow trench isolation structure 40 and semiconductor substrate 12. A hardmask material 50, e.g., silicon nitride or other known hardmask material, may be formed over the ferroelectric material 30. The ferroelectric material 30 and the hardmask material 50 may be deposited by any conventional deposition methods including, for example, CVD. A photolithographic resist 52 may be deposited on the hardmask material 50 and patterned using methods as already described herein. In this representation, the patterned photolithographic resist 52 will expose the hardmask material 50 in region 210, while protecting the hardmask material 50 in region 200.

As representatively shown in FIG. 4D, through several etching processes, the hardmask 50 in region 210 can be removed, exposing the underlying ferroelectric material 30. The photolithographic resist 52 may be removed by conventional processes, e.g., ashing or stripants, exposing the remaining hardmask 50 in region 200. Thereafter, any exposed ferroelectric material 30 may be removed by a selective chemistry, with the hardmask material 50 protecting the underlying ferroelectric material 30 in region 200. The removal of the ferroelectric material 30 in region 210 will expose the hardmask 50 in region 210.

In FIG. 4E, the remaining portions of the hardmask are removed by any conventional etching process. For example, the hardmask may be removed by a selective chemistry as is known in the art such that no further explanation is needed for a complete understanding of the present disclosure. In this way, the etching steps will result in the ferroelectric material 30 remaining in region 200 and the gate dielectric material 42 remaining in region 210, on opposing sides of the shallow trench isolation structure 40.

In FIG. 4F, a metal material 32 and a polysilicon material 54 may be blanket deposited over the ferroelectric material 30 and the gate dielectric material 42 on both sides of the structure, e.g., regions 200, 210. The metal material 32 may be a workfunction metal used in logic devices, e.g., device 100 of FIG. 4G, as is known in the art such that no further explanation is required for a complete understanding of the present disclosure.

In FIG. 4G, the materials are patterned using conventional lithography and etching processes to form the logic device 100 and the base switch 105, e.g., ferroelectric material 30 and metal material 32. Thereafter halo implants including source and drain regions for the logic device 100 and diffusion regions for the device 10 may be implanted, followed by a spike anneal process as is known in the art. Silicide block material, e.g., nitride, and a subsequent silicide contact formation may be performed as already described herein.

The contacts 34, 36 (with contacts to the source and drain region of the logic device 100) can be formed by formed by conventional lithography, etching and deposition processes as known in the art. By way of example, the contacts 34, 36 may be formed by the deposition of an interlevel dielectric material, followed by etching processes to form trenches exposing the diffusion regions. A metal material, e.g., TiN, Al, etc., may be deposited within the trenches, followed by a conventional chemical mechanical polishing (CMP) process.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a lateral bipolar transistor; and
a ferroelectric switching element electrically coupled to the lateral bipolar transistor.

2. The structure of claim 1, wherein the ferroelectric switching element contacts an underlying semiconductor substrate of the lateral bipolar transistor.

3. The structure of claim 1, wherein the lateral bipolar transistor comprises:
a base region;
a collector region adjacent to the base region; and
an emitter region adjacent to the collector region.

4. The structure of claim 3, wherein the base region surrounds the collector region and the collector region surrounds the emitter region.

5. The structure of claim 3, wherein the ferroelectric switching element is between the collector region and the emitter region.

6. The structure of claim 3, further comprising a shallow trench isolation structure isolating the base region and the collector region.

7. The structure of claim 1, wherein the ferroelectric switching element sits on a well in a semiconductor substrate.

8. The structure of claim 1, wherein the ferroelectric switching element comprises ferroelectric material and a metal material over the ferroelectric material.

9. The structure of claim 8, wherein the ferroelectric material comprises a single layer of ferroelectric material.

10. The structure of claim 8, wherein the ferroelectric material comprises multiple layers of ferroelectric material.

11. The structure of claim 8, further comprising a contact to independently supply voltage to the ferroelectric material.

12. The structure of claim 11, further comprising a logic device on a same semiconductor substrate as the ferroelectric material.

13. A structure comprising:
a lateral bipolar transistor comprising:
a first diffusion region;
a second diffusion region adjacent to the first diffusion region; and
a third diffusion region adjacent to the second diffusion region;
an independently controlled ferroelectric material between the second diffusion region and the third diffusion region; and
a contact electrically coupled to the ferroelectric material.

14. The structure of claim 13, wherein the ferroelectric material is electrically coupled to the lateral bipolar transistor.

15. The structure of claim 13, wherein the base region surrounds the collector region and the collector region surrounds the emitter region.

16. The structure of claim 13, further comprising a shallow trench isolation structure isolating the base region and the collector region, and the ferroelectric material surrounds the emitter region.

17. The structure of claim 13, wherein the ferroelectric switching element sits on a well in a semiconductor substrate.

18. The structure of claim 13, further comprising metal material over the ferroelectric material and the contact independently supplies voltage to the ferroelectric material.

19. The structure of claim 13, further comprising a logic device on a same semiconductor substrate as the ferroelectric material.

20. A method comprising:
forming a lateral bipolar transistor; and
forming a ferroelectric switching element electrically coupled to the lateral bipolar transistor.
